(19) United States
(12) Patent Application Publication
(10) Pub. No.: US 2002/0052720 A1
(43) Pub. Date: May 2, 2002

(54) Analytical data-writable, general-purpose analysis system, analytical data-writable, general-purpose analysis program, and recording medium which records the analytical data-writable, general-purpose analysis program

(75) Inventor: Hirokazu Nishiura, Kyoto (JP)

Correspondence Address: ARMSTRONG,WESTERMAN & HATTORI, LLP, 1725 K STREET, NW., SUITE 1000, WASHINGTON, DC, 20006, US

(73) Assignee: SEKISUI CHEMICAL CO., LTD., Osaka-shi (JP)

(21) Appl. No.: 09/983,344

(22) Filed: Oct. 24, 2001

(30) Foreign Application Priority Data
Oct. 26, 2000 (JP) 2000-327241
Oct. 4, 2001 (JP) 2001-308775

(51) Int. Cl. H03F 1/26; G06F 15/00; H04B 15/00

(52) U.S. Cl. 702/189

(57) ABSTRACT

This system comprises a display unit 1 which displays an analysis procedure screen for an object; a general-purpose analysis procedure file unit 62a for storing a general-purpose analysis procedure program which is commonly applied to various analysis objects; a screen display program storage unit 3 which stores the program for displaying an analytical data description screen, the program allowing the display unit 1 to display the analytical data description screen on which analytical data specific to a given analysis object is described; and an analytical data storage unit 4 which stores the analytical data on the given object, the analytical data being described on the analytical data description screen. An analysis computing unit 5 executes analysis computing for the given object, based on the general-purpose analysis procedure program stored in the general-purpose analysis procedure file unit 62a and also based on the analytical data on the given object stored in the analytical data storage unit 4.

### BACKGROUND OF THE INVENTION

(1) Applicable Field of the Invention

The present invention relates to an analytical data-writable, general-purpose analysis system, an analytical data-writable, general-purpose analysis program, and a recording medium on which the analytical data-writable, general-purpose analysis program is recorded, each of which is utilized in the field of computer simulation for evaluating product qualities (e.g. strength, rigidity) and the field of computer simulation for studying designs to optimize drawing qualities.

(2) Prior Art

Traditionally, when the CAE analysis technology is utilized to design various products, expert analysts need to carry out complicated strength calculation or the like to find a proper product design. In other words, not everyone can conduct CAE analysis in the conventional manner. This is because CAE analysis, which is based on the physical laws expressed by differential equations, requires a user to understand not only differential equations but also mathematical rules that are indispensable for the numerical analysis.

With regard to a variety of analysis methods, including CAE analysis, many attempts have been made with a view to improving the operability. For example, Japanese Patent Laid-open Publication No. H10-303267 discloses a technology applicable to a semiconductor production process. Its analysis device comprises an inspection data-gathering computer which is linked with every inspection apparatus via a network, and an analysis computer which analyzes the data acquired from the data-gathering computer. In this analysis device, the analysis computer stores and preserves a plurality of analysis contents and analysis procedures for different objectives. During the analysis, the computer reads out suitable preserved contents, based on which the analysis proceeds automatically. This technology has saved the trouble of repeating the same operation procedure in one analysis after another, thereby improving the operability of analyses.

The customized navigation system, such as the one disclosed above, not only provides the most suitable navigation style for each type of products, but also enables analytical data to be described. However, it is difficult to modify this navigation system in subsequent operations, and, what is more, such change will cost enormous time and labor. After all, a lot of time is consumed for the creation of software.

### SUMMARY OF THE INVENTION

An object of the present invention is to provide an analytical data-writable, general-purpose analysis system, an analytical data-writable, general-purpose analysis program, and a recording medium on which the analytical data-writable, general-purpose analysis program is recorded, in each of which the general-purpose operation part adopts a versatile operation procedure in the navigation style, whereas the analytical data part allows users to make free descriptions. Thereby, the present invention not only facilitates the development and use of a navigation system in compliance with every type of product but also saves the software development cost.

With respect to a general-purpose analysis system which stores a program concerning a procedure of CAE analysis, an analytical data-writable, general-purpose analysis system of the present invention comprises: means for storing analytical data on a given object, the analytical data being described on an analytical data description screen; and means for executing analysis computing for the given object, the execution of analysis computing being based on a general-purpose analysis procedure program which is commonly applied to various analysis objects, and also based on the analytical data on the given object which is stored in the analytical data storage means.

According to the present invention with the above characteristics, the analytical data description screen (e.g. an HTML-format screen or space) to be filled with analytical data descriptions is provided in every step of the analysis procedure. Owing to this arrangement, an operator having specialized knowledge about CAE analysis can describe analytical data regarding a given analysis object onto the analytical data description screen. As a result, the general-purpose analysis software can be made into special-purpose analysis software which is dedicated to the analysis of the given object, by modifying the analytical data part. While the conventional art involves the trouble of creating the whole of special-purpose analysis software from scratch in order to deal with individual analysis objects, the present invention can remarkably cut the time for developing analysis software and reduce the development cost.

Besides, with respect to a general-purpose analysis system which stores a program concerning a procedure of CAE analysis, an analytical data-writable, general-purpose analysis system of the present invention comprises: means for displaying an analysis procedure screen for an object; means for storing a general-purpose analysis procedure program, the general-purpose analysis procedure program being commonly applied to various analysis objects; means for storing a screen display program related to an analytical data description, the screen display program allowing the display means to display an analytical data description screen on which analytical data specific to a given analysis object is described; means for storing analytical data on the given object, the analytical data being described on the analytical data description screen; and means for executing analysis computing for the given object, the execution of analysis computing being based on the general-purpose analysis procedure program which is stored in the general-purpose analysis procedure program storage means, and also based on the analytical data on the given object which is stored in the analytical data storage means.

According to the present invention with the above characteristics, an HTML-format screen or space to be filled with analytical data descriptions is provided in every step of the analysis procedure. Owing to this arrangement, an operator having specialized knowledge about CAE analysis can describe analytical data regarding a given analysis object onto the analytical data description screen. As a result, the general-purpose analysis software can be made into special-purpose analysis software which is dedicated to the analysis of the given object, by modifying the analytical data part. While the conventional art involves the trouble of creating the whole of special-purpose analysis software from scratch in order to deal with individual analysis objects, the present invention can remarkably cut the time for developing analysis software and reduce the development cost.

In such analytical data-writable, general-purpose analysis systems of the present invention, the analytical data storage means stores analytical data on various objects, the analytical data being described on the analytical data description screen. Besides, each analysis system may comprise means for retrieving analytical data on a specified given object from the analytical data storage means, so as to execute analysis of the given object. In this case, the analysis computing means executes analysis computing for the given object, based on the general-purpose analysis procedure program which is stored in the general-purpose analysis procedure program storage means, and also based on the analytical data on the given object which is retrieved from the analytical data storage means by the analytical data retrieval means.

According to the present invention with the above characteristics, the described analytical data is separately accumulated for every object, so that a piece of general-purpose analysis software can serve as special-purpose analysis software dedicated to more than one type of objects. Consequently, the present invention can remarkably cut the time for developing analysis software and reduce more development cost. As another advantage, this arrangement can accomplish a user-friendly general-purpose analysis system. Incidentally, the program concerning a procedure of CAE analysis may be an interactive program.

Further, the analytical data-writable, general-purpose analysis system of the present invention can be provided as an analytical data-writable, general-purpose analysis program, and also as a recording medium on which the analytical data-writable, general-purpose analysis program is recorded. In other words, with regard to a general-purpose analysis processing program which stores a program concerning a procedure of CAE analysis, an analytical data-writable, general-purpose analysis program of the present invention comprises the steps of: storing analytical data on a given object within means for storing the analytical data, the analytical data being described on an analytical data description screen; and executing analysis computing for the given object, based on a general-purpose analysis procedure program which is commonly applied to various analysis objects, and also based on the analytical data on the given object which is stored in the analytical data storage means.

Furthermore, with regard to a general-purpose analysis processing program which stores a program concerning a procedure of CAE analysis, an analytical data-writable, general-purpose analysis program of the present invention comprises the steps of: allowing display means to display an analysis procedure screen for an object; storing a general-purpose analysis procedure program within means for storing the general-purpose analysis procedure program, the general-purpose analysis procedure program being commonly applied to various analysis objects; storing a screen display program related to an analytical data description within means for storing the screen display program related to an analytical data description, the screen display program allowing the display means to display an analytical data description screen on which analytical data specific to a given analysis object is described; storing analytical data on the given object within means for storing the analytical data, the analytical data being described on the analytical data description screen; and executing analysis computing for the given object, based on the general-purpose analysis procedure program which is stored in the general-purpose analysis procedure program storage means, and also based on the analytical data on the given object which is stored in the analytical data storage means.

In such analytical data-writable, general-purpose analysis programs of the present invention, the analysis program may further comprise the step of retrieving analytical data on a specified given object from the analytical data storage means, so as to execute analysis of the given object. In this case, the analysis computing step executes analysis computing for the given object, based on the general-purpose analysis procedure program, and also based on the analytical data on the given object which is retrieved from the analytical data storage means in the analytical data retrieval step.

### BRIEF DESCRIPTION OF THE DRAWINGS

FIG. 1 is a block diagram showing the conceptual configuration of the analytical data-writable, general-purpose analysis system according to an embodiment of the present invention.

FIG. 2 is a block diagram showing the conceptual configuration of the analytical data-writable, general-purpose analysis system according to another embodiment of the present invention.

FIG. 3 is an explanatory illustration showing an example of the initial screen which appears when the database is opened.

FIG. 4 is an explanatory illustration showing an example of the analysis solver selection screen.

FIG. 5(a) is an explanatory illustration showing an example of the model reading screen (for selection), and FIG. 5(b) is an explanatory illustration showing an example of the screen for specifying the model units.

FIG. 6(a) is an explanatory illustration showing an example of the model reading screen (for confirmation), and FIG. 6(b) is an explanatory illustration showing an example of the model confirmation screen.

FIG. 7(a) is an explanatory illustration showing an example of the mesh generation screen, and

FIG. 7(b) is an explanatory illustration showing an example of the analytical data description screen.

FIG. 8 is an explanatory illustration showing an example of the mesh generation screen.

FIG. 9 is an explanatory illustration showing an example of the mesh generation screen.

FIG. 10(a) is an explanatory illustration showing an example of the mesh generation screen, and

FIG. 10(b) is an explanatory illustration showing an example of the screen for entering the average element length.

FIG. 11(a) is an explanatory illustration showing an example of the screen for defining material properties, and FIG. 11(b) is an explanatory illustration showing an example of the analytical data description screen.

FIG. 12(a) is an explanatory illustration showing an example of the boundary condition setting screen, and FIG. 12(b) is an explanatory illustration showing an example of the analytical data description screen.

FIG. 13 is an explanatory illustration showing an example of the boundary condition setting screen.

FIG. 14 is an explanatory illustration showing an example of the boundary condition setting screen.

FIG. 15(a) is an explanatory illustration showing an example of the enforced displacement definition screen. FIG. 15(b) is an explanatory illustration showing an example of the screen for defining enforced displacement on an edge. FIG. 15(c) is an explanatory illustration showing an example of the screen for defining enforced displacement on a node.

FIG. 16 is an explanatory illustration showing an example of the display screen based on the set and defined boundary conditions.

FIG. 17 is an explanatory illustration showing an example of the load condition setting screen.

FIG. 18 is an explanatory illustration showing an example of the input file creation screen.

FIG. 19(a) is an explanatory illustration showing an example of the result processing screen, and

FIG. 19(b) represents displacement contour plots.

FIG. 20 is a flow chart of the analysis procedure which includes a sequence of steps described with reference to FIG. 3 to FIG. 19.

### DESCRIPTION OF THE PREFERRED EMBODIMENTS

Preferred embodiments of the present invention are hereinafter described with reference to the drawings.

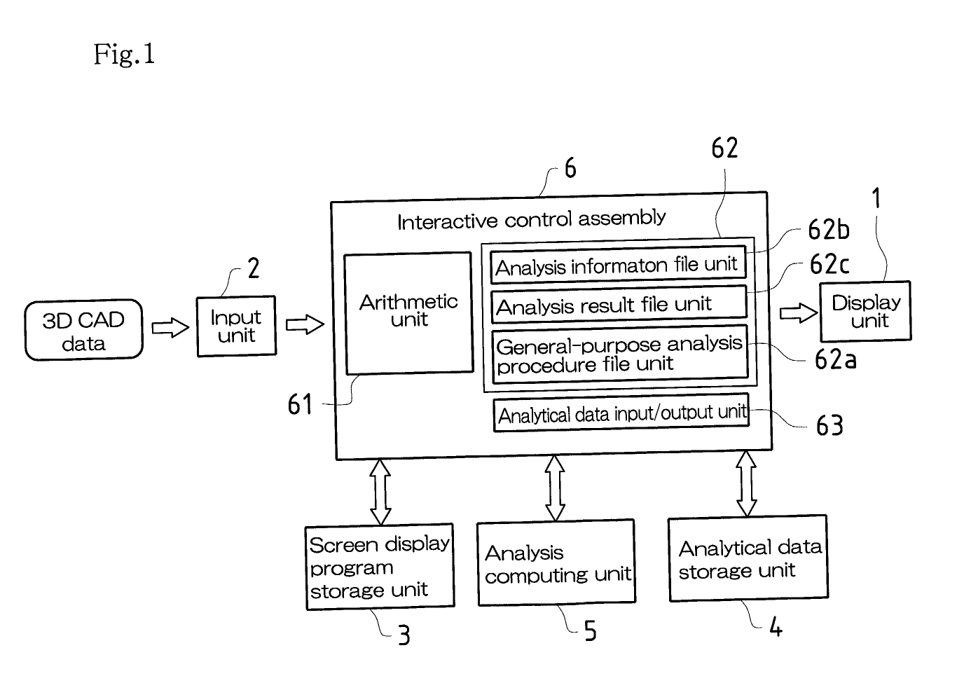

FIG. 1 is a conceptual block diagram showing the analytical data-writable, general-purpose analysis system according to an embodiment of the present invention.

Broadly speaking, the general-purpose analysis system comprises a display unit 1, an input unit 2, a unit 3 for storing screen display programs, a unit 4 for storing analytical data, an analysis computing unit (analysis solver) 5, and an interactive control assembly 6. In detail, the display unit 1 displays an analysis procedure screen for an object and an analytical data description screen. The input unit 2 is composed of a mouse, a keyboard, etc., which are used to make optional operations on the analysis procedure screen displayed in the display unit 1 and which are also used to describe the analytical data on the analytical data description screen displayed in the display unit 1. The unit 3 for storing screen display programs stores a screen display program related to the analysis procedure, according to which each analysis procedure screen is sequentially displayed in the display unit 1 in response to the operation of the input unit 2. The unit 3 also stores a screen display program related to the description of analytical data, according to which a corresponding analytical data description screen is displayed in the display unit 1, when an optional operation by means of the input unit 2 is effected on each analysis procedure screen displayed in the display unit 1. The analytical data storage unit 4 stores analytical data for a given object which is described on the analytical data description screen displayed in the display unit 1. The analysis computing unit (analysis solver) 5 conducts analysis in accordance with the information entered by the input unit 2. The interactive control assembly 6 is responsible for the control and computing at each of the above-mentioned units.

With regard to the interactive control assembly 6, it includes an arithmetic unit 61, a file storage section 62, and an analytical data input/output unit 63. The arithmetic unit 61 is a part (pre/post-processor) for computing the element geometry, mesh refinement, etc. in the actual analysis. The file storage section 62 stores a general-purpose analysis procedure file unit 62a for storing a general-purpose analysis procedure program which is commonly applicable to versatile analysis objects, an analysis information file unit 62b for accumulating analysis information on an analysis object which is entered on the respective input screens by the input unit 2, and an analysis result file unit 62c for accumulating the analysis results.

The analytical data input/output unit 63 executes the operation of storing analytical data in the analytical data storage unit 4, when the analytical data is described on a blank analytical data description screen displayed in the display unit 1. During execution of an analysis, the analytical data input/output unit 63 executes the operation of reading out appropriate analytical data stored in the analytical data storage unit 4 and transmitting the data to the analysis computing unit 5.

The analysis computing unit 5 executes analysis computing for a given object, based on the general-purpose analysis procedure program which is stored in the general-purpose analysis procedure file unit 62a of the file storage section 62, and also based on the analytical data on each step (procedure) which is read out from the analytical data storage unit 4. For this purpose, the analysis computing unit 5 is equipped with optimization software as well as CAE software for injection molding (called analysis solver) which conducts analysis of an object (neither are shown).

For the description of analytical data, the interactive control assembly 6 executes the operation of displaying the analytical data description screen in the display unit 1, based on the screen display program which is related to the description of analytical data and stored in the screen display program storage unit 3. Following this operation, when analytical data on a given object is described on the analytical data description screen by an operator having specialized knowledge of CAE analysis, the interactive control assembly 6 executes the operation of storing the described analytical data in the analytical data storage unit 4 via the analytical data input/output unit 63.

In executing the analysis, the interactive control assembly 6 executes the operation of displaying a series of analysis information input screens in the display unit 1, based on the programs stored in the screen display program storage unit 3, and the operation of accumulating, in the analysis information file unit 62b, the analysis information entered on the input screen. Once an object is analyzed by the analysis computing unit 5, based on the analysis information accumulated in the analysis information file unit 62b, the interactive control assembly 6 executes the operation of accumulating the analysis results in the analysis result file unit 62c.

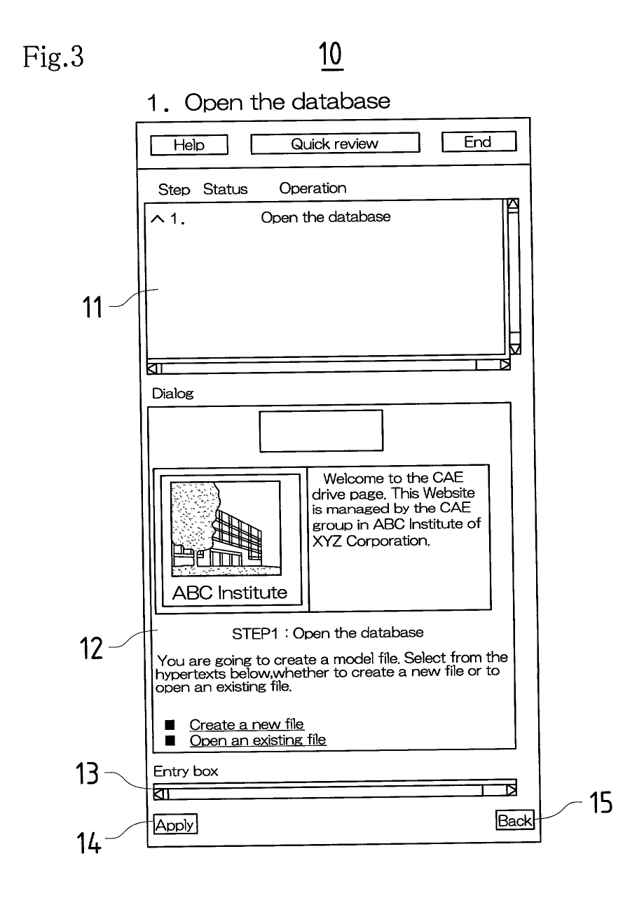

FIG. 3 to FIG. 18 represent the input screens and analytical data description screens to be sequentially displayed in the display unit 1. These screens are displayed in response to the input operation by the input unit 2, based on the screen display programs stored in the screen display program storage unit 3 (i.e. the input screen display program, and the screen display program related to the description of analytical data).

Basically, each of the input screens contains three sections. The top section constitutes a step display window for indicating the progress of steps in the analysis procedure. The middle section is a display window for showing the detailed analysis procedure. The bottom section serves as an input window for entry of numeric values, characters, etc. with respect to various parameters. As for the analytical data description screen, its initial screen is a simple blank screen.

In this embodiment, the general-purpose analysis procedure program comprises the steps (procedure) in the following order: the database opening step, the model reading step, the mesh generation step, the material definition step, the boundary condition setting step, the load condition setting step, the input file creation step, and the result display step. In each step, the principal part is linked to a rewritable analytical data description file. The analytical data description file is writable in HTML format in this embodiment, whereas it may be described in text format as well.

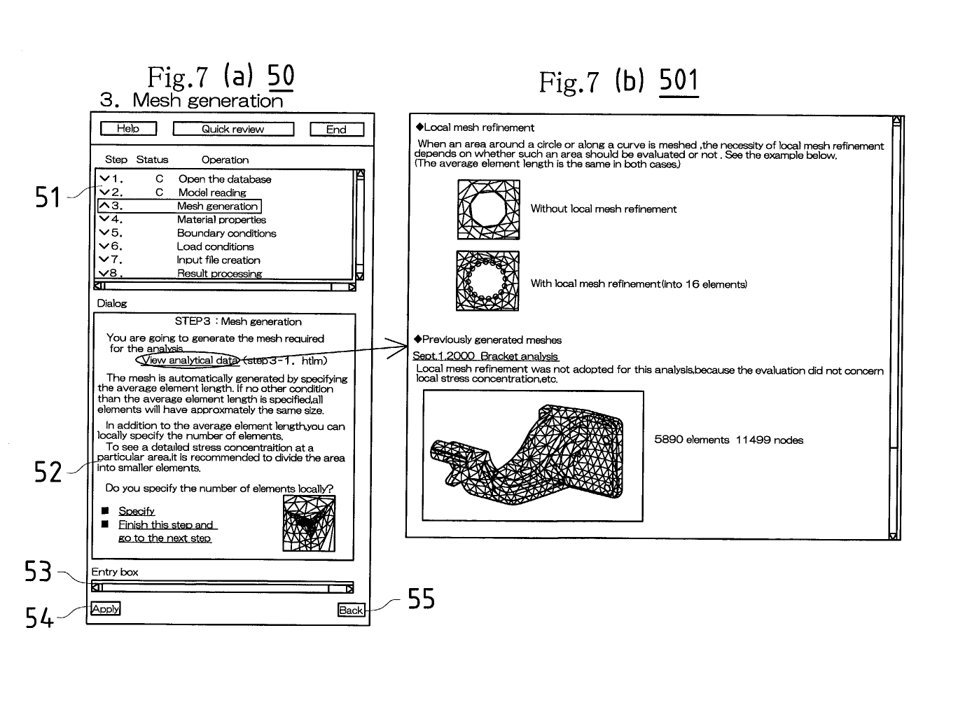

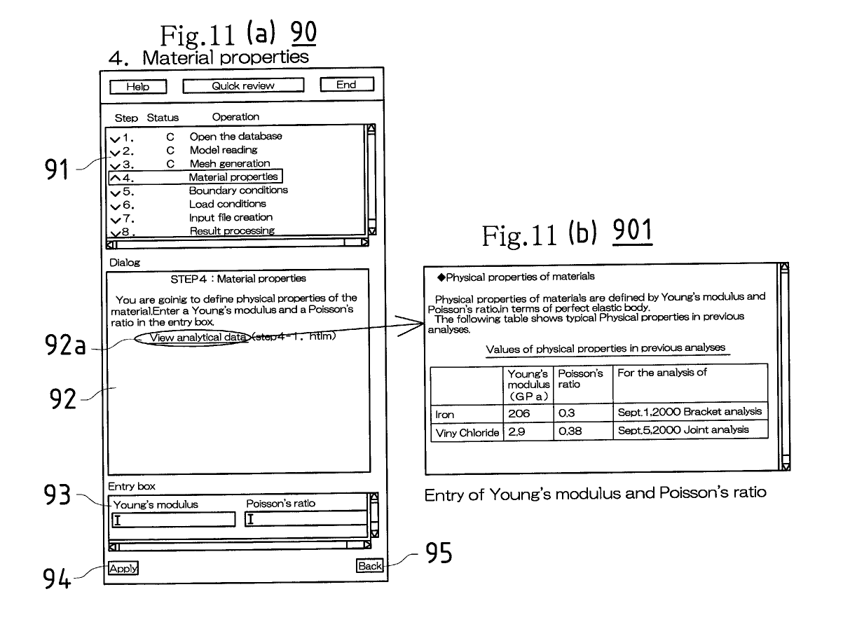

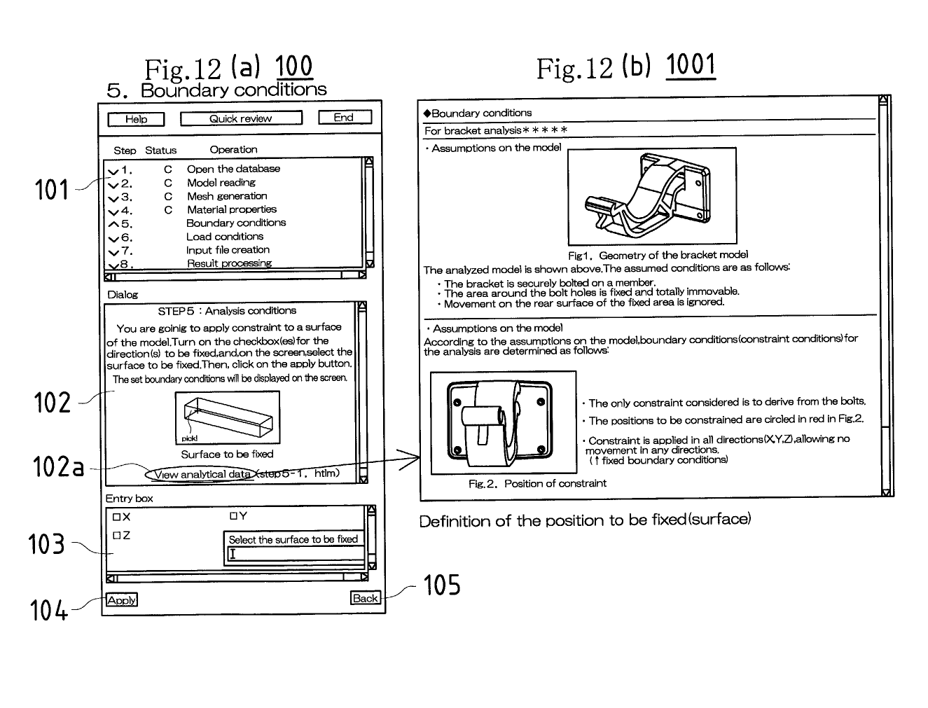

To give a few examples from the present embodiment, the mesh generation screen of FIG. 7(a), the material definition screen of FIG. 11(a), and the boundary condition setting screen of FIG. 12(a) are linked to separate analytical data description files on which analytical data can be described. The detailed descriptions of the analytical data are given in FIG. 7(b), FIG. 11(b) and FIG. 12(b), respectively.

In order to make description of analytical data, first of all, an operator having specialized knowledge of CAE analysis opens the input screen for each step shown in FIG. 3 to FIG. 18 (to be detailed later) according to the general-purpose analysis procedure program stored in the general-purpose analysis procedure file unit 62a. Then, the operator clicks on the message “View analytical data” given on the input screen, thereby to open the analytical data description screen (blank screen) which is prepared for (i.e. linked from) the input screen of the current step. On this analytical data description screen, the operator describes specific analytical data for a given object to be analyzed (The analysis object in the present embodiment is a bracket.). The analytical data can be described, for example, in the same manner as creating a homepage on the Internet, so that everyone can easily make such description.

Once the analytical data necessary for a bracket is described on the analytical data description screen prepared for (or linked from) each step, the general-purpose analysis software functions as the special-purpose analysis software dedicated to a bracket. Accordingly, an analyzer (user) is capable of analyzing a bracket by the bracket-specific analysis operation. The described analytical data is stored in the analytical data storage unit 4.

The following paragraphs relate to the process of analyzing a bracket. In this analysis, use is made of the general-purpose analysis system of the present embodiment which contains analytical data described in the above manner.

FIG. 3 shows a first screen (initial screen) 10 which appears on opening of the database. The initial screen 10 includes a step display window 11 for indicating the progress of steps in the analysis procedure, a display window 12 for interactively displaying the detailed analysis procedure, an input window 13 for entry of numeric values, characters, etc. with respect to various parameters, an apply button 14 marked “Apply” for applying the input contents, and a back button 15 marked “Back” for returning to the previous screen.

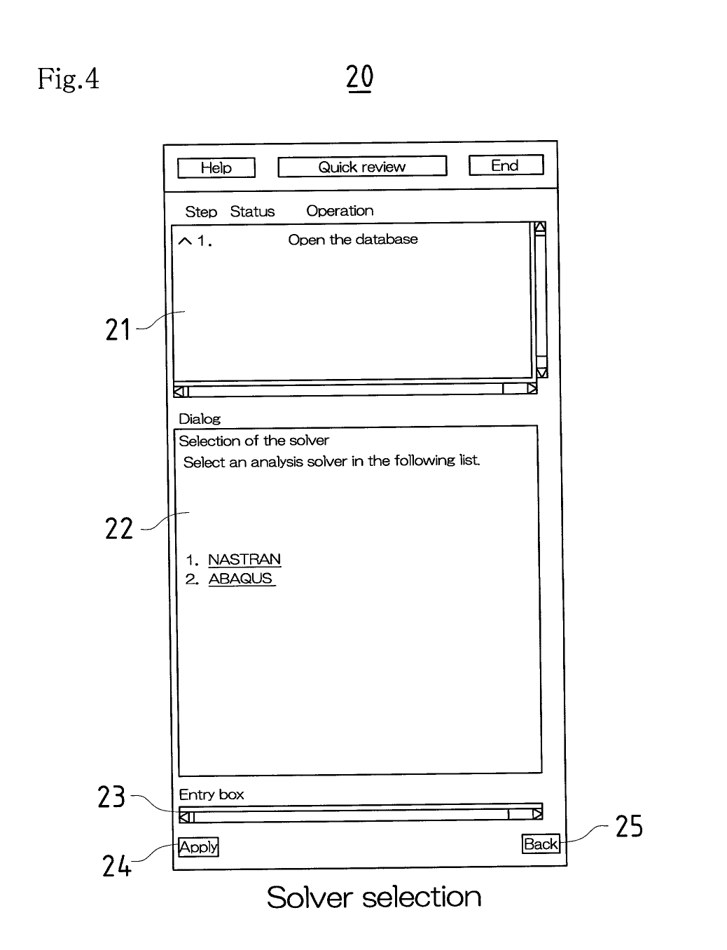

FIG. 4 shows a screen 20 for selecting the analysis solver. The analysis solver selection screen 20 includes a step display window 21 for indicating which input step has been completed, a selection display window 22 for interactively displaying appropriate messages in order to select an analysis solver to be executed, an input window 23 for entry of numeric values, characters, etc. with respect to various parameters, an apply button 24 marked “Apply” for applying the input contents, and a back button 25 marked “Back” for returning to the previous screen (the initial screen 10).

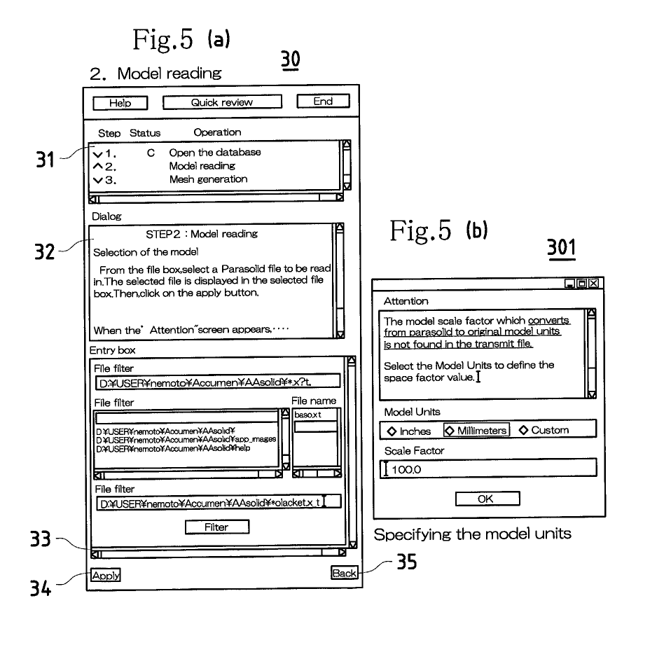

FIG. 5(a) shows a screen 30 for reading (selecting) the model. The model reading screen 30 (for selection) includes a step display window 31 for indicating which input steps have been completed, a display window 32 for displaying the contents of the current step, a selection input window 33 which prompts analyzer's selection by displaying file names of pre-arranged geometry models (Models of various geometries are prepared in meshed form.), an apply button 34 marked “Apply” for applying the selection, and a back button 35 marked “Back” for returning to the previous screen (the analysis solver selection screen 20). FIG. 5(b) depicts a screen 301 for specifying the model units.

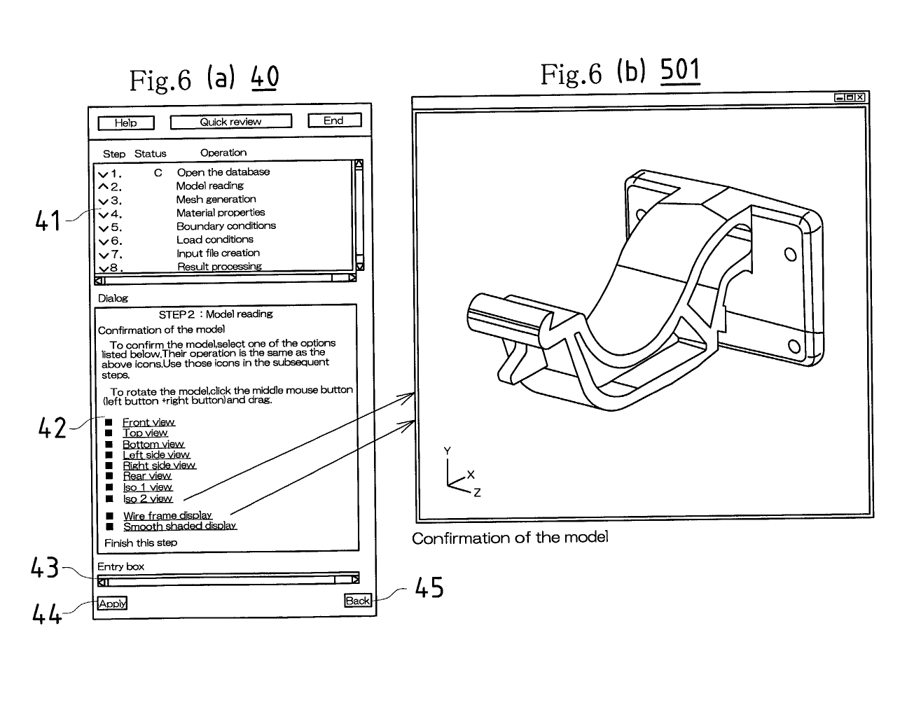

FIG. 6(a) shows a screen 40 for reading (confirming) the model. The model reading screen 40 (for confirmation) includes a step display window 41 for indicating which input steps have been completed, a display window 42 for displaying the contents of the current step, a confirmation window 43 for confirming the model selected by an analyzer, an apply button 44 marked “Apply” for applying the selection, and a back button 45 marked “Back” for returning to the previous screen (the model reading screen 30 (for selection). FIG. 6(b) depicts a screen 401 for representing the selected model geometry.

FIG. 7(a) shows a screen 50 for generating the mesh. The mesh generation screen 50 includes a step display window 51 for indicating which input steps have been completed, a display window 52 for interactively displaying the mesh generation method, an input window 53 for entry of numeric values, characters, etc. with respect to various parameters, an apply button 54 marked “Apply” for applying the input contents, and a back button 55 marked “Back” for returning to the previous screen (the model reading screen 40 (for confirmation)).

In addition, FIG. 7(b) shows a screen 501 for analytical data descriptions which appears at a click of the message “View analytical data” given in the display window 52 on the mesh generation screen 50. The analytical data description screen 501 displays detailed data on the mesh generation for a bracket, which has been described before by an operator.

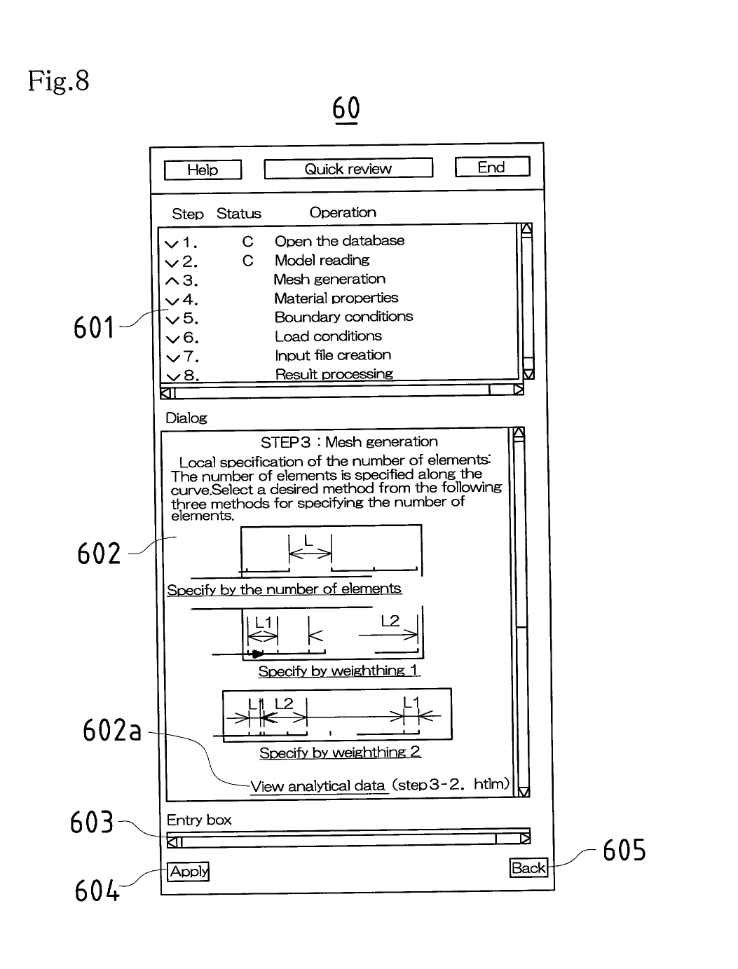

FIG. 8 shows a screen 60 for generating (locally refining) the mesh which appears at a click of the message “Specify” given in the display window 52 on the mesh generation screen 50 of FIG. 7. The mesh generation screen 60 (for local refinement) includes a step display window 601 for indicating which input steps have been completed, a display window 602 for displaying the methods of locally specifying the number of elements, an input window 603 for entry of numeric values, characters, etc. with respect to various parameters, an apply button 604 marked “Apply” for applying the selected method or the input contents, and a back button 605 marked “Back” for returning to the previous screen (the mesh generation screen 50).

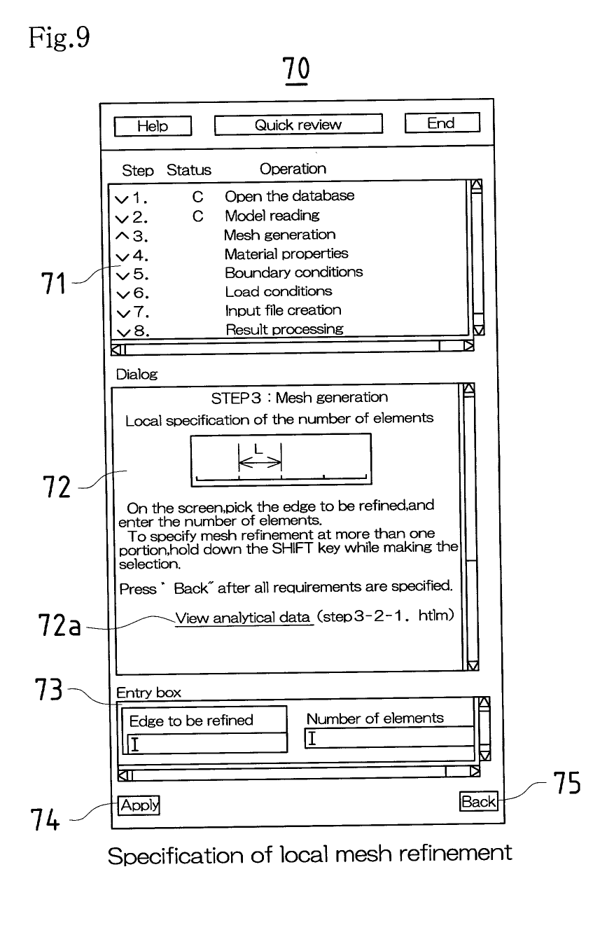

FIG. 9 shows a screen 70 for generating the mesh (locally specifying the number of elements) which appears at a click of a particular specification method displayed in the display window 602 on the mesh generation screen 60 (for local refinement) of FIG. 8. The mesh generation screen 70 (for local specification of the number of elements) includes a step display window 71 for indicating which input steps have been completed, a display window 72 for displaying details of the selected specification method (“Specify by the number of elements” is supposed to be selected.), an input window 73 for entry of an edge subjected to mesh refinement as well as the number of elements, an apply button 74 marked “Apply” for applying the input contents, and a back button 75 marked “Back” for returning to the previous screen (the mesh generation screen 60 (for local refinement).

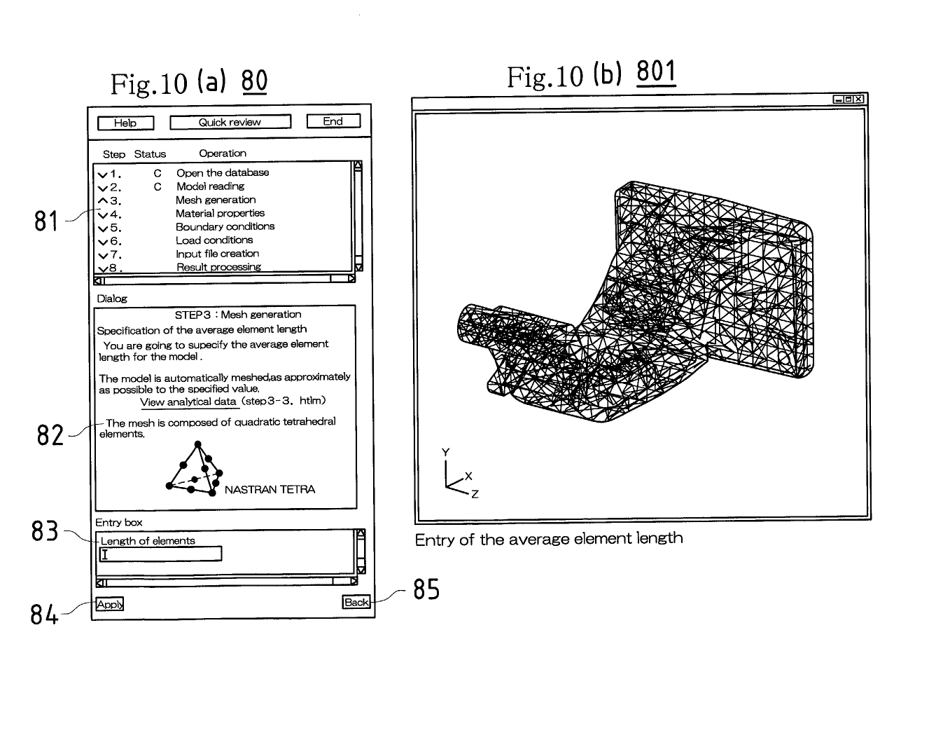

FIG. 10(a) shows a screen 80 for generating the mesh (specifying the average element length). The mesh generation screen 80 (for specification of the average element length) includes a step display window 81 for indicating which input steps have been completed, a display window 82 for displaying how to specify the average element length, an input window 83 for entry of an element length, an apply button 84 marked “Apply” for applying the input contents, and a back button 85 marked “Back” for returning to the previous screen (the mesh generation screen 70 (for local specification of the number of elements)). FIG. 10(b) represents an input screen 801 for the average element length.

FIG. 11(a) shows a screen 90 for defining material properties. The material definition screen 90 includes a step display window 91 for indicating which input steps have been completed, a display window 92 for displaying input contents about various physical properties of materials, an input window 93 for entry of a Young's modulus and a Poisson's ratio, an apply button 94 marked “Apply” for applying the input contents, and a back button 95 marked “Back” for returning to the previous screen (the mesh generation screen 80 (for specification of the average element length)). In addition, FIG. 11(b) shows a screen 901 for analytical data descriptions which appears at a click of the message “View analytical data” given in the display window 92 on the material definition screen 90. The analytical data description screen 901 displays detailed data on the material definition for a bracket, which has been described before by an operator.

FIG. 12(a) shows a screen 100 for setting boundary conditions, on which the fixed position on the surface is defined. The boundary condition setting screen 100 includes a step display window 101 for indicating which input steps have been completed, a display window 102 for interactively displaying the boundary conditions required for the analysis, an input window 103 for entry of various boundary conditions, an apply button 104 marked “Apply” for applying the input contents, and a back button 105 marked “Back” for returning to the previous screen (the material definition screen 90). In addition, FIG. 12(b) shows a screen 1001 for analytical data descriptions which appears at a click of the message “View analytical data” given in the display window 102 on the boundary condition setting screen 100. The analytical data description screen 1001 displays detailed data on the boundary conditions for a bracket, which has been described by an operator.

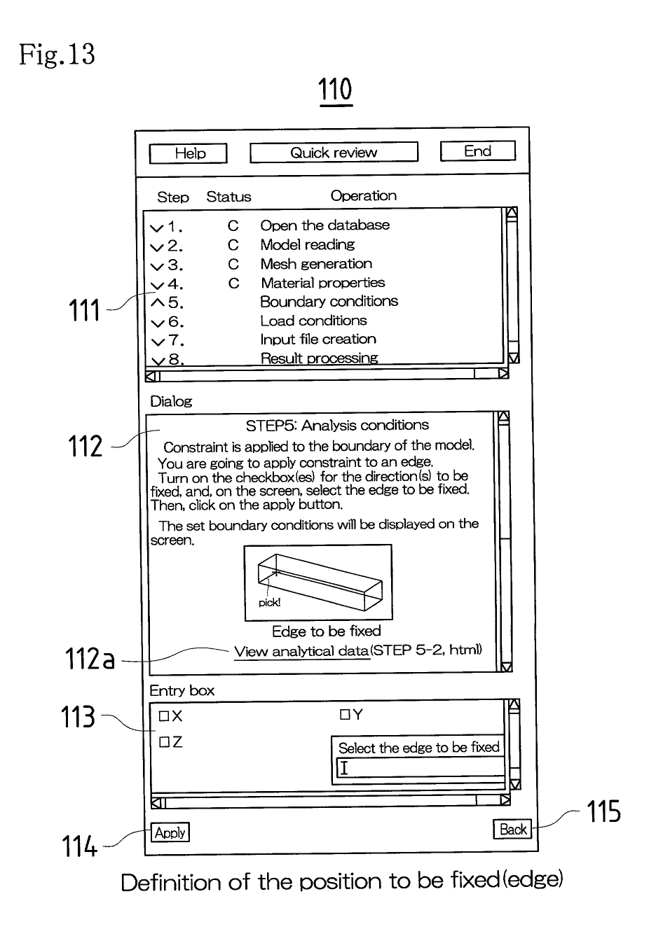

FIG. 13 shows a screen 110 for setting boundary conditions, on which the fixed position on the edge is defined. The boundary condition setting screen 110 includes a step display window 111 for indicating which input steps have been completed, a display window 112 for interactively displaying the boundary conditions required for the analysis, an input window 113 for entry of various boundary conditions, an apply button 114 marked “Apply” for applying the input contents, and a back button 115 marked “Back” for returning to the previous screen (the boundary condition setting screen 100).

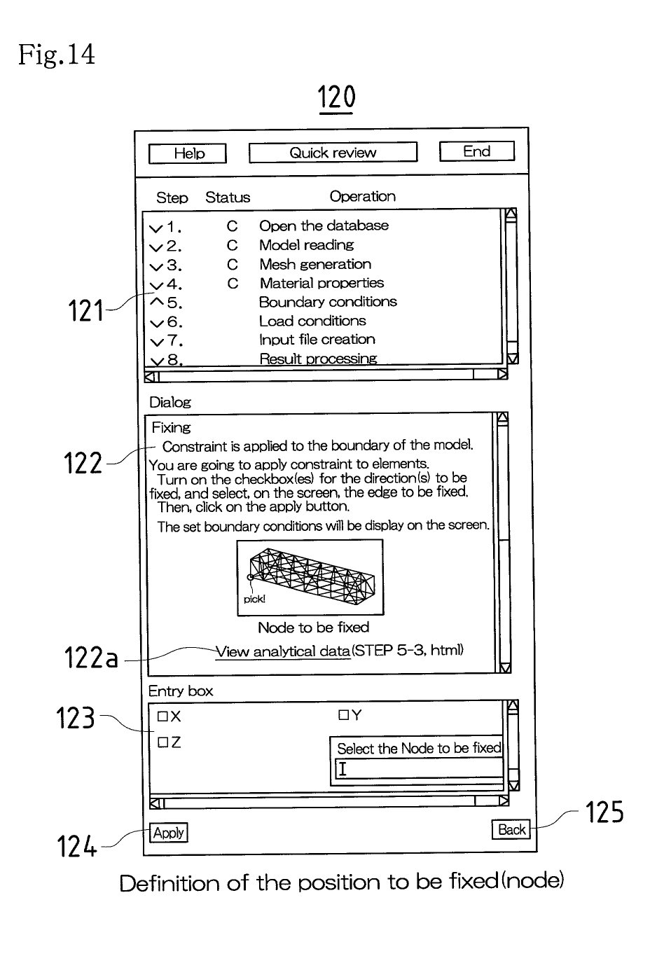

FIG. 14 shows a screen 120 for setting boundary conditions, on which the fixed position on the node is defined. The boundary condition setting screen 120 includes a step display window 121 for indicating which input steps have been completed, a display window 122 for interactively displaying the boundary conditions required for the analysis, an input window 123 for entry of various boundary conditions, an apply button 124 marked “Apply” for applying the input contents, and a back button 125 marked “Back” for returning to the previous screen (the boundary condition setting screen 110).

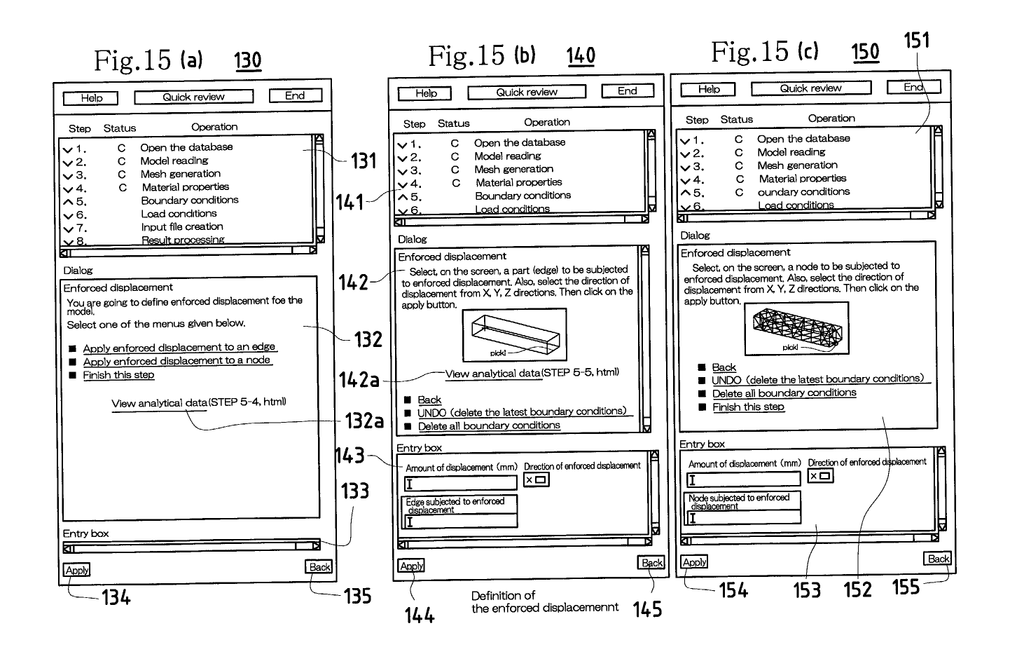

FIG. 15(a) shows a screen 130 for defining enforced displacement. The enforced displacement definition screen 130 includes a step display window 131 for indicating which input steps have been completed, a display window 132 for interactively displaying the explanation of enforced displacement, an input window 133 for entry of numeric values, characters, etc. with respect to various parameters, an apply button 134 marked “Apply” for applying the input contents, and a back button 135 marked “Back” for returning to the previous screen (the boundary condition setting screen 120).

FIG. 15(b) shows a screen 140 for defining enforced displacement, which appears at a click of the message “Apply enforced displacement to an edge” shown in the display window 132 on the enforced displacement definition screen 130 of FIG. 15(a). The enforced displacement definition screen 140 includes a step display window 141 for indicating which input steps have been completed, a display window 142 for interactively displaying how to apply enforced displacement to an edge, an input window 143 for entry of the amount of displacement, the direction of enforced displacement, and an edge subjected to enforced displacement, an apply button 144 marked “Apply” for applying the input contents, and a back button 145 marked “Back” for returning to the previous screen (the enforced displacement definition screen 130).

FIG. 15(c) shows a screen 150 for defining enforced displacement, which appears at a click of the message “Apply enforced displacement to a node” shown in the display window 132 on the enforced displacement definition screen 130 of FIG. 15(a). The enforced displacement definition screen 150 includes a step display window 151 for indicating which input steps have been completed, a display window 152 for interactively displaying how to apply enforced displacement to a node, an input window 153 for entry of the amount of displacement, the direction of enforced displacement, and a node subjected to enforced displacement, an apply button 154 marked “Apply” for applying the input contents, and a back button 155 marked “Back” for returning to the previous screen (the enforced displacement definition screen 130).

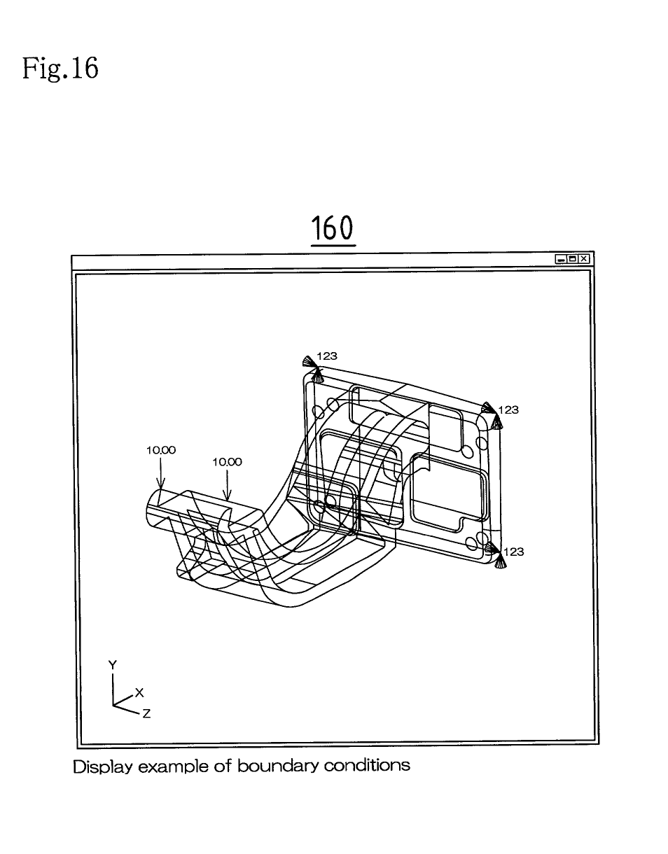

FIG. 16 represents a screen 160 for displaying the boundary conditions which are set and defined on the boundary condition setting screen 100, the boundary condition setting screen 110, the boundary condition setting screen 120, the enforced displacement definition screen 140, and the enforced displacement definition screen 150, shown in FIG. 12 to FIG. 15.

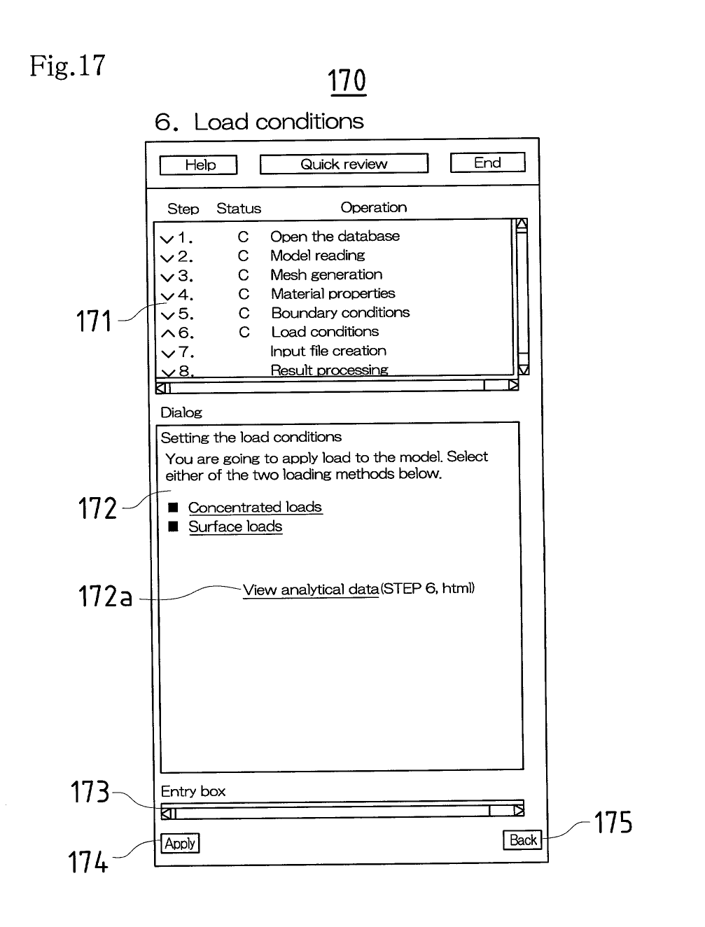

FIG. 17 shows a screen 170 for setting load conditions. The load condition setting screen 170 includes a step display window 171 for indicating which input steps have been completed, a display window 172 for interactively displaying the load conditions, an input window 173 for entry of numeric values, characters, etc. with respect to various parameters, an apply button 174 marked “Apply” for applying the input contents, and a back button 175 marked “Back” for returning to the previous screen (the enforced displacement definition screen 130).

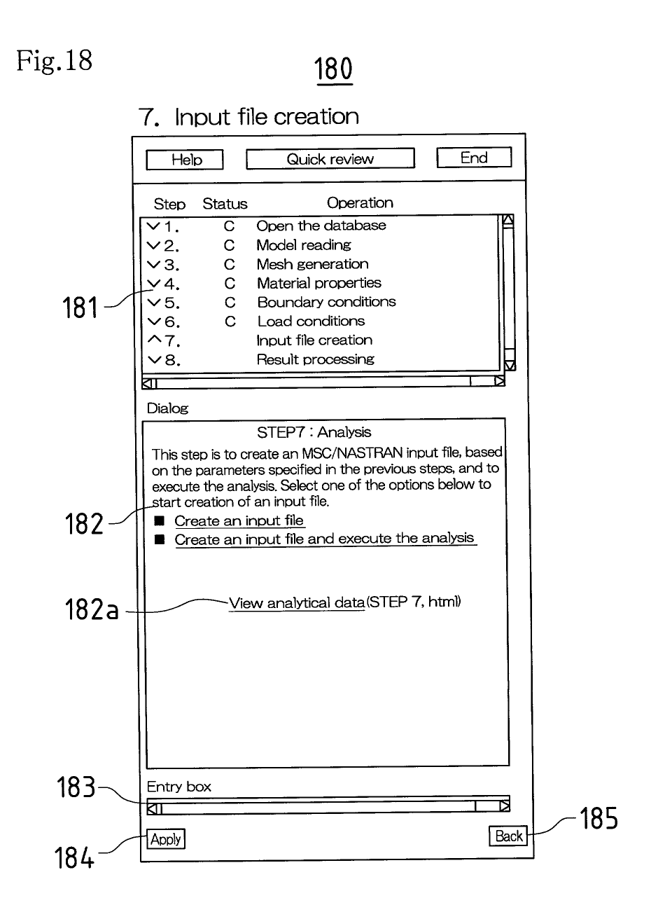

FIG. 18 shows a screen 180 for creating an input file. The input file creation screen 180 includes a step display window 181 for indicating which input steps have been completed, a display window 182 for interactively displaying the messages to prompt the analyzer to create an input file, an input window 183 for entry of numeric values, characters, etc. with respect to various parameters, an apply button 184 marked “Apply” for applying the input contents, and a back button 185 marked “Back” for returning to the previous screen (the load condition setting screen 170).

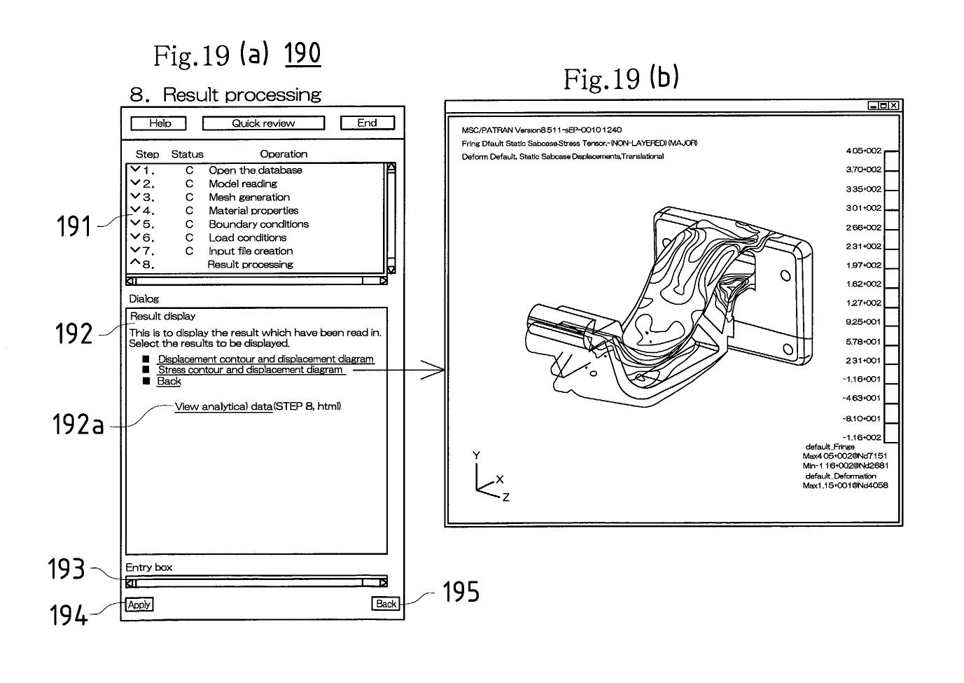

FIG. 19(a) shows a screen 190 for processing the results. The result processing screen 190 includes a step display window 191 for indicating which input steps have been completed, a display window 192 for displaying the analysis results, an input window 193 for entry of numeric values, characters, etc. with respect to various parameters, an apply button 194 marked “Apply” for applying the input content, and a back button 195 marked “Back” for returning to the previous screen (the input file creation screen 180). In addition, FIG. 19(b) depicts an example of contour plots which appear at a click of the message “Stress contour and displacement diagram” in the display window 192 on the result processing screen 190.

Although detailed descriptions are skipped, the clickable message “View analytical data” is displayed in the display windows 52, 602, 72, 82, 92, 102, 112, 122, 132, 142, 172, 182, 192 on the input screens shown in FIG. 7 to FIG. 19 (except FIG. 16). Hence, any analyzer can refer to the analytical data on the corresponding step by clicking on the message “View analytical data”. However, in the case where no analytical data has been described by an operator onto the analytical data description screen, a blank screen is to appear.

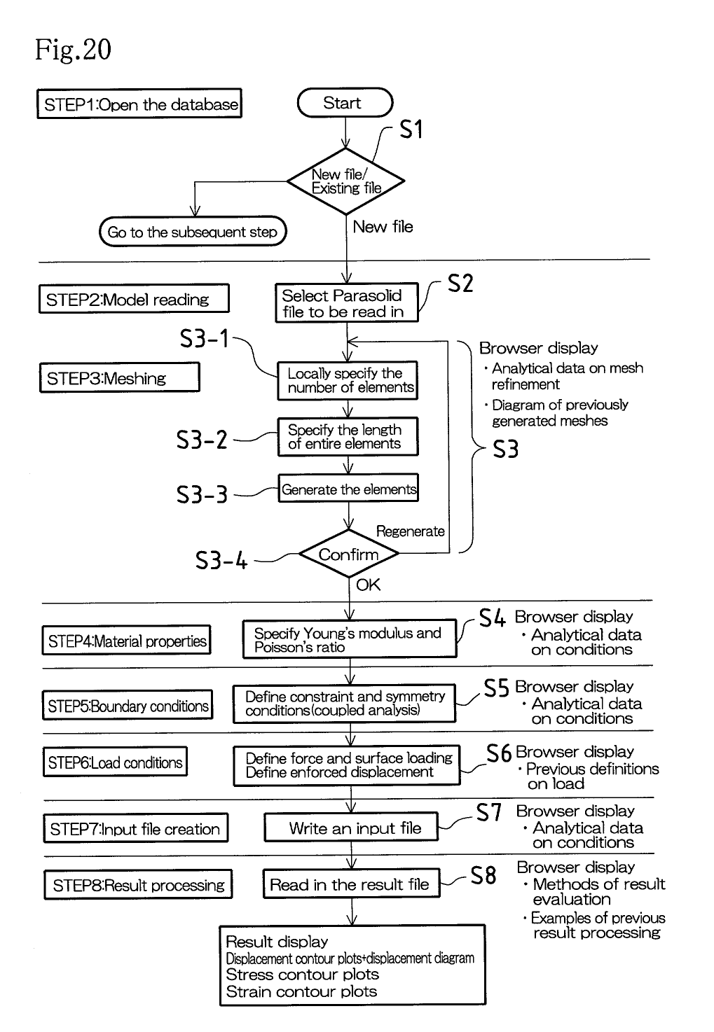

The following paragraphs are directed to the procedure of analyzing and designing a bracket by means of the above analysis system dedicated to a bracket. In the course of description, reference is made to the above-mentioned exemplary input screens and analysis result display screen shown in FIG. 3 to FIG. 19. In addition, a flow chart given in FIG. 20 is also referenced.

To begin with, an analyzer starts up the present device, allowing the initial screen 10 of FIG. 3 to appear in the display unit 1. The analyzer then selects either “Create a new file” or “Open an existing file” in the display window 12 (step S1). For the purpose of explanation, suppose “Create a new file” is selected. Incidentally, if “Open an existing file” is selected, the system opens an existing modeling database of previous analyses.

In response to the selection of “Create a new file”, the interactive control assembly 6 activates the screen display program which is stored in the screen display program storage unit 3, thereby allowing the display unit 1 to display the analysis solver selection screen 20 shown in FIG. 4. From the contents given in the selection display window 22 of the analysis solver selection screen 20, the analyzer selects an analysis solver to be used in the current analysis. Specifically, in order to select any of the analysis solvers displayed in the selection display window 22, the analyzer places the cursor over the character portion of a desired item, clicks on this character potion, and then clicks on the apply button 24 with the mouse or the like.

Following this operation, the display unit 1 displays the model reading screen 30 shown in FIG. 5(a), together with the screen 301 shown in FIG. 5(b) for specifying the model units.

The selection input window 33 of the model reading screen 30 lists file names of various geometry models. To select one geometry model in meshed form, the analyzer selects one of the file names (at a click of the mouse, etc.) and clicks on the apply button 34 with the mouse, etc. (step S2). Following this selection, the display unit 1 displays the model reading screen 40 (for confirmation) shown in FIG. 6(a).

In the model reading screen 40 (for confirmation), the analyzer can confirm the model which has been read in. The model confirmation screen 401 of FIG. 6(b) is displayed by selecting any of the options given in the display window 42 (at a click of the mouse, etc.).

After the model is confirmed, the analyzer proceeds to click on the apply button 44 in the model reading screen 40 (for confirmation). Thereby, the display unit 1 displays the mesh generation screen 50 shown in FIG. 7(a), while the analysis information file unit 62b accumulates the mesh data which has been read in (Suppose a solid model is read in).

In the next step, the analyzer generates a mesh necessary for the analysis, as instructed in the display window 52 of the mesh generation screen 50 (step S3). In this step, if the message 52a “View analytical data” in the display window 52 is clicked on with the mouse, etc., the display unit 1 displays the analytical data description screen 501 shown in FIG. 7(b). The analytical data description screen 501 provides not only the explanation on local mesh refinement but also a mesh or meshes generated in the past. The analyzer can determine the necessity of local refinement, with referring to this explanation on local refinement. Back to the mesh generation screen 50 of FIG. 7 (a), in case local refinement is required, the analyzer clicks on the message 52b “Specify” in the display window 52 with the mouse, etc. Then, the display unit 1 displays the mesh generation screen 60 (for local refinement) shown in FIG. 8.

Incidentally, it will be helpful to make a brief description of the step display window. In the step display window, the symbols “V” appearing at the left of some steps indicate that those steps are not selected at the moment. In contrast, the currently selected step is indicated with the symbol “Λ” (inverted V) shown at the left of the step. Taking FIG. 8 as an example, the third step (Mesh generation) is marked with “Λ”. In addition, the symbols “C” beside some step numbers signify that these steps have been already selected and that entries in these steps are completed (In FIG. 8, the steps of “Open the database” and “Model reading” are marked with “C”.). This display style is common to the step display windows on all input screens to be described below.

To continue the procedure, turning to the display window 602 of the mesh generation screen 60 (for local refinement), the analyzer selects one of the three methods for specifying the local refinement. In making the selection, the analyzer can refer to the analytical data on the local refinement for a bracket, by clicking with the mouse, etc. on the message 602a “View analytical data” in the display window 602 (Illustration of the corresponding screen is omitted.). If no data has been described on the analytical data description file, a blank screen will appear.

The analyzer, who may make reference to the analytical data as necessary, clicks with the mouse, etc. on any of the messages in the display window 602 (namely, “Specify by the number of elements”, “Specify by weighting 1” or “Specify by weighting 2”). Provided that the message “Specify by the number of elements” is clicked on, the display unit 1 displays the mesh generation screen 70 (for local specification of the number of elements) shown in FIG. 9. The analyzer enters the edge to be refined and the number of elements into the input window 73, as instructed in the display window 72 of the mesh generation screen 70 (for local specification of the number of elements) (step S3-1). Also in this step, the analyzer can refer to the analytical data on how to locally specify the number of elements for a bracket, by clicking on the message 72a “View analytical data” in the display window 72 with the mouse, etc. (Illustration of the corresponding screen is omitted.).

Afterwards, the analyzer enters the average element length for the model into the input window 83, as instructed in the display window 82 of the mesh generation screen 80 (for specification of the average element length) shown in FIG. 10(a) (step S3-2). Likewise, the analyzer can refer to the analytical data on how to specify the average element length for a bracket, by clicking on the message 82a “View analytical data” in the display window 82 with the mouse, etc. (Illustration of the corresponding screen is omitted.). Based on the respective element data thus specified, the mesh data on a bracket is generated and displayed in the display unit 1 (see FIG. 10(b)). This presentation enables on-screen confirmation of the mesh data for the analyzer. In case the mesh needs to be regenerated, the analyzer returns to the step of locally specifying the number of elements and repeats the above-mentioned mesh generation steps (step S3-3, step S3-4). Otherwise, the analyzer clicks on the apply button 84 with the mouse, etc. Then, the display unit 1 displays the material definition screen 90 shown in FIG. 11, while the analysis information file unit 62b accumulates the generated element data.

On the material definition screen 90, the analyzer enters a Young's modulus and a Poisson's ratio into the input window 93, as instructed in the display window 92 (step S4). Similar to the above steps, if the analyzer clicks on the message 92a “View analytical data” in the display window 92 with the mouse, etc., the display unit 1 displays the analytical data description screen 901 which concerns physical properties of the materials, as given in FIG. 11(b). Hence, the analyzer can enter a Young's modulus and a Poisson's ratio into the input window 93, with referring to the analytical data. Having entered these values, the analyzer clicks on the apply button 94 with the mouse, etc. Thereby, the display unit 1 displays the boundary condition (surface) setting screen 100 of FIG. 12(a), while the analysis information file unit 62b accumulates the specified data on the physical properties of the material.

In the next step, as instructed in the display window 102 of the boundary condition (surface) setting screen 100, the analyzer turns on a checkbox in the input window 103 to specify any direction to be fixed, and selects the surface to be fixed (step S5). Similar to the above steps, if the analyzer clicks on the message 102a “View analytical data” in the display window 102 with the mouse, etc., the display unit 1 displays the analytical data description screen 1001 which concerns the boundary conditions for a bracket, as given in FIG. 12(b). Hence, the analyzer can determine the contents to be entered in the input window 103, with referring to the analytical data. Having entered the required conditions, the analyzer clicks on the apply button 104 with the mouse, etc. Thereby, the display unit 1 displays the boundary condition (edge) setting screen 110 of FIG. 13, while the analysis information file unit 62b accumulates the entered boundary conditions on the surface.

Further, as instructed in the display window 112 of the boundary condition (edge) setting screen 110, the analyzer turns on a checkbox in the input window 113 to specify any direction to be fixed, and selects the edge to be fixed (step S5). Similar to the above steps, if the analyzer clicks on the message 112a “View analytical data” in the display window 112 with the mouse, etc., the display unit 1 displays the analytical data description screen for a bracket (not shown) which relates to the boundary conditions on the edge. Hence, the analyzer can determine the contents to be entered in the input window 113, with referring to the analytical data. Having entered the required conditions, the analyzer clicks on the apply button 114 with the mouse, etc. Thereby, the display unit 1 displays the boundary condition (node) setting screen 120 of FIG. 14, while the analysis information file unit 62b accumulates the entered boundary conditions on the edge.

Furthermore, as instructed in the display window 122 of the boundary condition (node) setting screen 120, the analyzer turns on a checkbox in the input window 123 to specify any direction to be fixed, and selects the node to be fixed (step S5). Similar to the above steps, if the analyzer clicks on the message 122a “View analytical data” in the display window 122 with the mouse, etc., the display unit 1 displays the analytical data description screen for a bracket (not shown) which relates to the boundary conditions on the node. Hence, the analyzer can determine the contents to be entered in the input window 123, with referring to the analytical data. Having entered the required conditions, the analyzer clicks on the apply button 124 with the mouse, etc. Thereby, the display unit 1 displays the enforced displacement definition screen 130 of FIG. 15(a), while the analysis information file unit 62b accumulates the entered boundary conditions on the node.

Following the setting of boundary conditions, the analyzer defines enforced displacement of the model by selecting one of the menus given in the display window 132 of the enforced displacement definition screen 130 (step S6). Similar to the above steps, at a click of the message 132a “View analytical data” in the display window 132 with the mouse, etc., the analyzer can consult with the analytical data on the enforced displacement for a bracket (Illustration of the corresponding screen is omitted.). When the analyzer clicks on the message “Apply enforced displacement to an edge” from the menus provided in the display window 132, the display unit 1 displays the enforced displacement definition screen 140 with regard to the edge, as shown in FIG. 15(b).

According to the explanation given in the display window 142 of the enforced displacement definition screen 140, the amount of displacement, the edge subjected to enforced displacement, and the direction of enforced displacement are entered in the input window 143. Similarly, the analyzer can consult with the analytical data for a bracket which concerns the enforced displacement on the edge, by clicking on the message 142a “View analytical data” in the display window 142 with the mouse, etc. (Illustration of the corresponding screen is omitted.). Thereafter, the analyzer clicks on the apply button 144 with the mouse, etc., so that the analysis information file unit 62b accumulates the entered data which relates to the enforced displacement on the edge.

In the enforced displacement definition screen 130 of FIG. 15(a), the analyzer further clicks on the message “Apply enforced displacement to a node” from the menus provided in the display window 132. Then, the display unit 1 displays the enforced displacement definition screen 150 with regard to the node, as shown in FIG. 15(c).

Likewise, according to the explanation given in the display window 152 of the enforced displacement definition screen 150, the amount of displacement, the node subjected to enforced displacement, and the direction of enforced displacement are entered in the input window 153. Similarly, the analyzer can consult with the analytical data for a bracket which concerns the enforced displacement on the node, by clicking on the message 152a “View analytical data” in the display window 152 with the mouse, etc. (Illustration of the corresponding screen is omitted.). Thereafter, the analyzer clicks on the apply button 154 with the mouse, etc., so that the analysis information file unit 62b accumulates the entered data which relates to the enforced displacement on the node.

Based on the above setting, the display unit 1 displays the screen 160 for displaying the boundary conditions for a bracket, as illustrated in FIG. 16. The analyzer can consult with the screen 160 to judge whether the boundary conditions for a bracket have been set properly.

Having confirmed the boundary conditions, the analyzer clicks on the message “Finish this step” from the menus given in the display window 132 of the enforced displacement definition screen 130 (FIG. 15(a)). In turn, the display unit 1 presents the load condition setting screen 170 shown in FIG. 17.

In order to define the load conditions, the analyzer selects one of the menus given in the display window 172 of the load condition setting screen 170 (step S6). Similarly, the analyzer can consult with the analytical data on the load conditions for a bracket, by clicking on the message 172a “View analytical data” in the display window 172. (Illustration of the corresponding screen is omitted.). Having referred to the analytical data as necessary, the analyzer selects either “Concentrated loads” or “Surface loads” indicated in the display window 172, and clicks on the apply button 174 with the mouse, etc. In turn, the display unit 1 displays the input file creation screen 180 shown in FIG. 18, while the analysis information file unit 62b accumulates the entered load conditions.

For creation of an input file, the analyzer selects one of the menus given in the display window 182 of the input file creation screen 180 (step S7). Similarly, the analyzer can consult with the analytical data on the file creation, by clicking on the message 182a “View analytical data” in the display window 182 (Illustration of the corresponding screen is omitted.). In the case where the analyzer clicks on the message “Create an input file” displayed in the display window 182 with the mouse, etc. and then on the apply button 184, the procedure ends with creation of the input file.

On the other hand, the analyzer may click on the message “Create an input file and execute the analysis” with the mouse, etc. At a click of the apply button 184 with the mouse, etc., an input file is created first, and the analysis computing unit 5 thereafter carries out the analysis based on the created input file (Note that the input file is stored in the analysis information file unit 62b.). The analysis results are stored in the analysis result file unit 62c.

Referring to FIG. 19(a), when the analysis result file is read out from the analysis result file unit 62c, the result processing screen 190 is displayed in the display unit 1 (step S8). On this result processing screen 190, the analyzer selects one of the menus given in the display window 192. Provided that “Stress contour and displacement diagram” is selected, the display unit 1 exhibits the displacement contour plots as depicted in FIG. 19(b). Similar to the above steps, the analyzer can refer to the analytical data by clicking on the message 192a “View analytical data” given in the display window 192 (Illustration of the corresponding screen is omitted.).

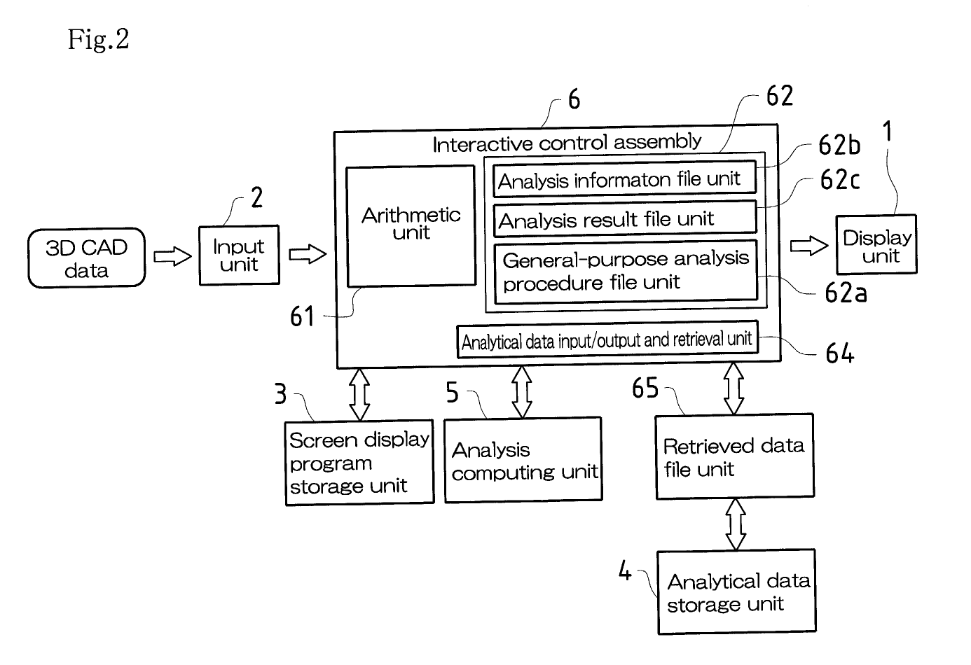

FIG. 2 is a conceptual block diagram showing the analytical data-writable, general-purpose analysis system according to another embodiment of the present invention.

In the general-purpose analysis system of this embodiment, the analytical data retrieval function is added to the general-purpose analysis system shown in FIG. 1.

In other words, the analytical data input/output unit 63 in FIG. 1 is replaced with an analytical data input/output and retrieval unit 64 which incorporates a retrieval unit, and a retrieved data file unit 65 is provided between the analytical data input/output and retrieval unit 64 and the analytical data storage unit 4. Otherwise, the system configuration of the second embodiment is entirely identical to that of the general-purpose analysis system shown in FIG. 1. Hence, the other constituents are identified by the same signs and not described in detail.

The analytical data storage unit 4 is arranged to store analytical data on various objects, when the data is described on the analytical data description screen by an operator. To execute analysis of a given object as specified by an operator, the analytical data which corresponds to the given object is retrieved from the analytical data storage unit 4 via the retrieved data file unit 65. With this arrangement, a piece of general-purpose analysis software is capable of serving as the special-purpose analysis software dedicated to various objects.

The above analytical data-writable, general-purpose analysis system is realized by means of an analytical data-writable, general-purpose analysis program.

In addition, the subject of the present invention is understood to encompass the program itself and a computer-readable recording medium which stores this program.

As the recording medium, the present invention may utilize program media constituted with a memory (e.g. ROM) necessary for the operation in the interactive control assembly 6 shown in FIG. 1 and FIG. 2. Alternatively, program media may be equipped with an external storage unit like a program reader (not shown) which is capable of reading an inserted recording medium.

In this respect, the program media is defined as a recording medium which is separable from the main body, including magnetic disks such as FD (flexible disk) and HD (hard disk), optical disks such as CD-ROM/MO/MD/DVD, cards such as IC card/optical card, semiconductor memories such as mask ROM, EPROM, EEPROM, flash ROM, etc.

The system configuration of the present invention is not connectable with the communication networks including the Internet. However, where the system configuration can establish connections to the communication networks, the recording medium may dynamically hold a program by downloading it from the communication networks.

This application is based on Japanese patent application Nos. 2000-327241 and 2001-308775, the content of which is incorporated hereinto by reference.

What is claimed is:

1. An analytical data-writable, general-purpose analysis system which stores a program concerning a procedure of CAE analysis, which system comprises:
means for storing analytical data on a given object, the analytical data being described on an analytical data description screen, and
means for executing analysis computing for the given object, the execution of analysis computing being based on a general-purpose analysis procedure program which is commonly applied to various analysis objects, and also based on the analytical data on the given object which is stored in the analytical data storage means.

2. An analytical data-writable, general-purpose analysis system which stores a program concerning a procedure of CAE analysis, which system comprises:
means for displaying an analysis procedure screen for an object,
means for storing a general-purpose analysis procedure program, the general-purpose analysis procedure program being commonly applied to various analysis objects,
means for storing a screen display program related to an analytical data description, the screen display program allowing the display means to display an analytical data description screen on which analytical data specific to a given analysis object is described,
means for storing analytical data on the given object, the analytical data being described on the analytical data description screen, and
means for executing analysis computing for the given object, the execution of analysis computing being based on the general-purpose analysis procedure program which is stored in the general-purpose analysis procedure program storage means, and also based on the analytical data on the given object which is stored in the analytical data storage means.

3. An analytical data-writable, general-purpose analysis system according to claim 1,
wherein the analytical data storage means stores analytical data on various objects, the analytical data being described on the analytical data description screen,
wherein the analysis system further comprises means for retrieving analytical data on a specified given object from the analytical data storage means, so as to execute analysis of the given object, and
wherein the analysis computing means executes analysis computing for the given object, based on the general-purpose analysis procedure program, and also based on the analytical data on the given object which is retrieved from the analytical data storage means by the analytical data retrieval means.

4. An analytical data-writable, general-purpose analysis system according to claim 2,
wherein the analytical data storage means stores analytical data on various objects, the analytical data being described on the analytical data description screen,
wherein the analysis system further comprises means for retrieving analytical data on a specified given object from the analytical data storage means, so as to execute analysis of the given object, and
wherein the analysis computing means executes analysis computing for the given object, based on the general-purpose analysis procedure program, and also based on the analytical data on the given object which is retrieved from the analytical data storage means by the analytical data retrieval means.

5. An analytical data-writable, general-purpose analysis system according to claim 1, wherein the program concerning a procedure of CAE analysis is an interactive program.

6. An analytical data-writable, general-purpose analysis system according to claim 2, wherein the program concerning a procedure of CAE analysis is an interactive program.

7. An analytical data-writable, general-purpose analysis program which is a computer-readable general-purpose analysis processing program and which stores a program concerning a procedure of CAE analysis, which program comprises the steps of:
storing analytical data on a given object within means for storing the analytical data, the analytical data being described on an analytical data description screen, and
executing analysis computing for the given object, based on a general-purpose analysis procedure program which is commonly applied to various analysis objects, and also based on the analytical data on the given object which is stored in the analytical data storage means.

8. An analytical data-writable, general-purpose analysis program which is a computer-readable general-purpose analysis processing program and which stores a program concerning a procedure of CAE analysis, which program comprises the steps of:
allowing display means to display an analysis procedure screen for an object,
storing a general-purpose analysis procedure program within means for storing the general-purpose analysis procedure program, the general-purpose analysis procedure program being commonly applied to various analysis objects,
storing a screen display program related to an analytical data description within means for storing the screen display program related to an analytical data description, the screen display program allowing the display means to display an analytical data description screen on which analytical data specific to a given analysis object is described,
storing analytical data on the given object within means for storing the analytical data, the analytical data being described on the analytical data description screen, and
executing analysis computing for the given object, based on the general-purpose analysis procedure program which is stored in the general-purpose analysis procedure program storage means, and also based on the analytical data on the given object which is stored in the analytical data storage means.

9. An analytical data-writable, general-purpose analysis program according to claim 7,
wherein the analysis program further comprises the step of retrieving analytical data on a specified given object from the analytical data storage means, so as to execute analysis of the given object, and
wherein the analysis computing step executes analysis computing for the given object, based on the general-purpose analysis procedure program, and also based on the analytical data on the given object which is retrieved from the analytical data storage means in the analytical data retrieval step.

10. An analytical data-writable, general-purpose analysis program according to claim 8,
wherein the analysis program further comprises the step of retrieving analytical data on a specific given object from the analytical data storage means, so as to execute analysis of the given object, and
wherein the analysis computing step executes analysis computing for the given object, based on the general-purpose analysis procedure program, and also based on the analytical data on the given object which is retrieved from the analytical data storage means in the analytical data retrieval step.

11. An analytical data-writable, general-purpose analysis program according to claim 7, wherein the program concerning a procedure of CAE analysis is an interactive program.

12. An analytical data-writable, general-purpose analysis program according to claim 8, wherein the program concerning a procedure of CAE analysis is an interactive program.

13. A computer-readable recording medium on which the analytical data-writable, general-purpose analysis program according to any of claims 7 to 12 is recorded.
